(19) United States
(12) Patent Application Publication
(10) Pub. No.: US 2022/0310414 A1
(43) Pub. Date: Sep. 29, 2022

(54) WET PROCESSING DEVICE AND CONTROL METHOD THEREFOR, STORAGE MEDIUM AND ELECTRONIC DEVICE

(71) Applicant: CHANGXIN MEMORY TECHNOLOGIES, INC., Hefei City, Anhui (CN)

(72) Inventor: Feng ZHANG, Hefei (CN)

(73) Assignee: CHANGXIN MEMORY TECHNOLOGIES, INC., Hefei City, Anhui (CN)

(21) Appl. No.: 17/593,035

(22) PCT Filed: Apr. 16, 2021
(86) PCT No.: PCT/CN2021/087786

§ 371 Date: Sep. 5, 2021

(30) Foreign Application Priority Data
May 6, 2020 (CN) 202010372869.4

(51) Int. Cl. H01L 21/67

(52) U.S. Cl. CPC H01L 21/67051; H01L 21/6715; H01L 21/6708

(57) ABSTRACT

A wet processing device includes a first channel, a nozzle, a second channel, and a sensor. The nozzle includes a spout communicated with the first channel. Negative pressure is formed in the second channel. The second channel includes an opening, the spout is located in the second channel, and the opening is located below the spout. The sensor is configured to detect whether there is liquid in the nozzle.

### CROSS-REFERENCE TO RELATED APPLICATIONS

The present disclosure claims priority to Chinese Patent Application No. 202010372869.4, entitled “WET PROCESSING DEVICE AND CONTROL METHOD THEREFOR, STORAGE MEDIUM AND ELECTRONIC DEVICE”, filed on May 6, 2020, which is incorporated herein by reference in its entirety.

### TECHNICAL FIELD

The present disclosure relates to the technical field of semiconductor production and manufacturing, and in particular to a wet processing device and a control method therefor, a storage medium and an electronic device.

### BACKGROUND

At present, the wet etching process (including wet cleaning) is a commonly used process for semiconductor production and manufacturing, in which a wafer may be cleaned by chemical liquid to reduce the contamination and defects of the wafer, and specific films may be etched isotropically to obtain a desired shape.

In the etching machine used in the wet etching process, liquid is sprayed by a nozzle. At the end of wet etching, because the spout of the nozzle faces down, the residual liquid in the nozzle and its connected pipe will naturally drop along the edge of the nozzle due to its own gravity and the ductility of liquid, that is, the liquid dropping. This will affect the surface of the wafer, thereby reducing the product yield.

### SUMMARY

The present disclosure provides a wet processing device and a control method therefor, a storage medium, and an electronic device, so as to solve the problem of liquid dropping during wet etching in the prior art.

According to a first aspect of the present disclosure, there is provided a wet processing device, comprising:

a first channel;

a nozzle comprising a spout, the nozzle being communicated with the first channel;

a second channel in which negative pressure is formed, the second channel comprising an opening, the spout being located in the second channel, the opening being located below the spout; and

a sensor configured to detect whether there is liquid in the nozzle.

In an embodiment of the present disclosure, the second channel comprises a tapered channel, and a small-diameter end of the tapered channel is the opening.

In an embodiment of the present disclosure, at least part of the first channel is a liquid supply pipeline, the nozzle is connected to the liquid supply pipeline, at least part of the second channel is a vacuum outer sleeve, the nozzle is located in the vacuum outer sleeve, and at least part of the liquid supply pipeline is located in the vacuum outer sleeve;

wherein, between the nozzle and the vacuum outer sleeve, and between the liquid supply pipeline and the vacuum outer sleeve, there is a gap for the liquid to circulate.

In an embodiment of the present disclosure, the wet processing device further comprises:

a liquid supply component, the other end of the first channel away from the nozzle being communicated with the liquid supply component;

wherein a first valve is provided on the first channel.

In an embodiment of the present disclosure, the wet processing device further comprises:

a vacuum generator, the other end of the second channel away from the opening being communicated with the vacuum generator;

wherein a second valve is provided on the second channel.

In an embodiment of the present disclosure, the wet processing device further comprises:

a controller, connected to the sensor and to the second valve, so as to control communication of the second channel through the second valve when the sensor detects that there is the liquid in the nozzle.

In an embodiment of the present disclosure, the controller comprises an alarm module that is triggered when the sensor detects that there is the liquid in the nozzle.

In an embodiment of the present disclosure, the wet processing device further comprises:

a third channel in which negative pressure is formed, the third channel being communicated with the first channel, and the third channel being set in a manner that it can be switched on or off.

In an embodiment of the present disclosure, the wet processing device further comprises:

a carrying table configured to carry a wafer, the carrying table comprising a receiving groove, the wafer is located in the receiving groove (81), the opening being arranged opposite to a notch of the receiving groove;

wherein the third channel is communicated with the receiving groove.

In an embodiment of the present disclosure, the third channel is a return pipeline, a third valve is provided on the return pipeline, and the return pipeline is communicated with the receiving tank through a branch return pipeline;

wherein the third channel comprises a first connection port connected to the first channel and a second connection port connected to the branch return pipeline, the third valve is located between the first connection port and the second connection port.

In an embodiment of the present disclosure, the wet processing device is a wet cleaning device, a wet etching device or a wet electroplating device.

According to a second aspect of the present disclosure, there is provided a control method for a wet processing device, comprising:

receiving a detection signal from a sensor;

determining, according to the detection signal, that there is liquid in a nozzle of a wet processing device; and

controlling the formation of negative pressure in a second channel of the wet processing device so that the liquid in the nozzle is pulled into the second channel.

In an embodiment of the present disclosure, the control method for a wet processing device further comprises:

controlling an alarm module to give an alarm while controlling the formation of negative pressure in the second channel.

In an embodiment of the present disclosure, the control method for a wet processing device further comprises:

controlling the formation of negative pressure in a third channel of the wet processing device, so as to pull the liquid in the first channel into the third channel; wherein the nozzle is communicated with the first channel.

According to a third aspect of the present disclosure, there is provided a computer-readable storage medium having a computer program stored thereon that, when executed by a processor, implements steps of the control method for a wet processing device described above.

According to a fourth aspect of the present disclosure, there is provided an electronic device, comprising:

a processor; and

a memory configured to store instructions executable by the processor,

wherein the processor is configured to execute the control method for a wet processing device described above by executing the executable instructions.

The wet processing device in the present disclosure detects whether there is liquid in the nozzle through the sensor, and can pull the liquid in the nozzle through the negative pressure formed in the second channel to prevent the liquid in the nozzle from dropping, thereby solving the problem of liquid dropping during the wet etching in the prior art.

### BRIEF DESCRIPTION OF THE DRAWINGS

Various objectives, features, and advantages of the present disclosure will become more apparent when considering the following detailed description of the preferred embodiments of the present disclosure with reference to the accompanying drawings. The drawings are merely schematic illustrations of the present disclosure, and are not necessarily drawn to scale. In the drawings, the same reference numerals always represent the same or similar parts. In the drawings:

FIG. 1 is a schematic structure diagram of a wet processing device according to an exemplary implementation;

FIG. 2 is an enlarged schematic structure diagram of part A of FIG. 1.

FIG. 3 is a schematic view of comparison of wafer structures obtained by wet processing devices before and after the improvement of liquid dropping;

FIG. 4 shows a schematic flowchart of a control method for a wet processing device;

FIG. 5 schematically shows a schematic view of a computer-readable storage medium in an exemplary embodiment of the present disclosure; and

FIG. 6 schematically shows a schematic view of an electronic device in an exemplary embodiment of the present disclosure.

### REFERENCE NUMERALS

1: wafer; 10: nozzle; 11: spout; 20: first channel; 21: first valve; 30: second channel; 31: opening; 32: tapered channel; 33: gap; 34: second valve; 40: sensor; 41: sending end; 42: receiving end; 50: liquid supply component; 60: vacuum generator; 70: third channel; 71: third valve; 72: branch return pipeline; 73: first connection port; 74: second connection port; 80: carrying table; 81: receiving groove; and 90: liquid recycle portion.

300: program product; 600: electronic device; 610: processing unit; 620: storage unit; 6201: random access memory (RAM); 6202: cache; 6203: read-only memory (ROM); 6204: program/utility; 6205: program module; 630: bus; 640: display unit; 650: input/output (I/O) interface; 660: network adapter; 700: external device.

### DETAILED DESCRIPTION

Typical embodiments embodying the features and advantages of the present disclosure will be described in detail below. It should be understood that the present disclosure may have various changes to different embodiments, without departing from the scope of the present disclosure, and the description and drawings therein are essentially for illustrative purposes, rather than limiting the present disclosure.

In the following description of different exemplary implementations of the present disclosure, reference is made to the accompanying drawings which form a part of the present disclosure and show, by way of example, different exemplary structures, systems, and steps that can implement various aspects of the present disclosure. It should be understood that other specific solutions of components, structures, exemplary devices, systems, and steps may be used, and structural and functional modifications may be made without departing from the scope of the present disclosure. Moreover, although the terms “above”, “between”, “within”, etc., may be used in this specification to describe different exemplary features and elements of the present disclosure, these terms are used herein for convenience only, for example, according to the direction of the examples in the drawings. Nothing in this specification should be understood as requiring a specific three-dimensional direction of the structure to fall within the scope of the present disclosure.

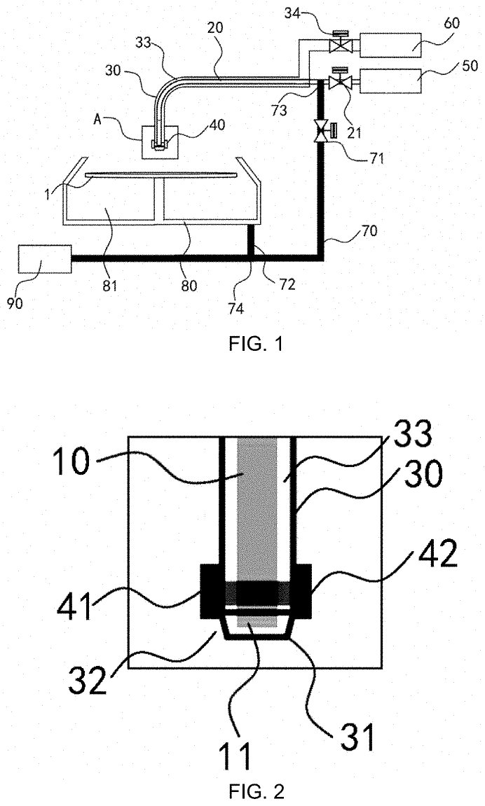

An embodiment of the present disclosure provides a wet processing device. Referring to FIGS. 1 and 2, the wet processing device comprises: a first channel 20; a nozzle 10 comprising a spout 11, the nozzle 10 being communicated with the first channel 20; a second channel 30 in which negative pressure is formed, the second channel 30 comprising an opening 31, the spout 11 being located in the second channel 30, the opening 31 being located below the spout 11; and a sensor 40 configured to detect whether there is liquid in the nozzle 10.

The wet processing device in an embodiment of the present disclosure detects whether there is liquid in the nozzle 10 through the sensor 40, and can pull the liquid in the nozzle 10 through the negative pressure formed in the second channel 30 to prevent the liquid in the nozzle 10 from dropping, thereby solving the problem of liquid dropping during the wet etching in the prior art.

In an embodiment, when the wet processing device is running (that is, liquid supply is required), it is necessary to provide liquid into the nozzle 10 through the first channel 20 and spray it through the spout 11 of the nozzle 10. When the liquid supply through the first channel 20 is stopped, because there may be residual liquid in the first channel 20, liquid dropping may occur. The sensor 40 can detect whether there is liquid in the nozzle 10 in real time, and when it is determined that there is liquid in the nozzle 10, negative pressure is formed in the second channel 30, which pulls the liquid flowing out through the spout 11 of the nozzle 10 into the second channel 30, thereby avoiding the liquid dropping.

In an embodiment, both the first channel 20 and the second channel 30 may be set in a manner that they can be switched on or off. When the wet processing device is running, the first channel 20 is switched on to provide liquid into the nozzle 10, and when the wet processing device stops running (that is, when no liquid supply is required), the first channel 20 is switched off so that the liquid cannot flow into the nozzle 10. When the second channel 30 is switched on, it may be considered that negative pressure is formed in the second channel 30, so that the liquid flowing out of the nozzle 10 may be pulled away. That is, when the sensor 40 determines that there is liquid in the nozzle 10, the second channel 30 is switched on.

In an embodiment, as shown in FIG. 2, the sensor 40 comprises:

a sending end 41 located on one side of the nozzle 10 and a receiving end 42 located on the other side of the nozzle 10, the sending end 41 and the receiving end 42 are arranged oppositely for monitoring whether there is liquid in the nozzle 10. The signal sent by the sending end 41 passes through the nozzle 10 and is received by the receiving end 42. When there is liquid in the nozzle 10, the signal strength will change. By the change in the signal strength, it may be determined that there is liquid in the nozzle 10.

In an embodiment, the sensor 40 is a photoelectric sensor, and the sending end 41 and the receiving end 42 are both arranged on the second channel 30 and located on the outer surface of the second channel 30; wherein, the second channel 30 and the nozzle 10 are both transparent parts. The photoelectric sensor is a sensor in which a photoelectric element is used as the detection element. First, the sensor converts the measured change into the change in an optical signal, and then further converts the optical signal into an electrical signal with the help of photoelectric elements. By providing the second channel 30 and the nozzle 10 as transparent parts, it is possible to ensure that light can go through them.

In an embodiment, as shown in FIG. 2, the second channel 30 comprises a tapered channel 32, and a small diameter end of the tapered channel 32 is the opening 31. The arrangement of the tapered channel 32 can increase the adsorption pressure in the second channel 30 so as to ensure that the liquid flowing out of the nozzle 10 can be reliably pulled into the second channel 30.

In an embodiment, the spout 11 is located in the middle of the radially tapered channel 32, that is, it is ensured that the spout 11 may be in a high negative pressure zone.

In an embodiment, at least part of the first channel 20 is a liquid supply pipeline to which the nozzle 10 is connected, at least part of the second channel 30 is a vacuum outer sleeve in which the nozzle 10 is located, and at least part of the liquid supply pipeline is located in the vacuum outer sleeve; wherein, between the nozzle 10 and the vacuum outer sleeve, and between the liquid supply pipeline and the vacuum outer sleeve, there is a gap 33 for the liquid to circulate. The vacuum outer sleeve is sleeved on the outside of the nozzle 10 and the liquid supply pipeline, and is arranged at intervals to form a gap 33. In this case, the nozzles 10 are all located in the vacuum outer sleeve. When there is liquid in the nozzle 10 and the liquid flows out of the spout 11, the liquid will be pulled away by the gap 33.

In an embodiment, part of the liquid supply pipeline is sleeved by the vacuum outer sleeve.

In an embodiment, as shown in FIG. 1, the first channels 20 are all liquid supply pipelines, and the second channels 30 are all vacuum outer sleeves. The nozzles 10 are all located in the vacuum outer sleeves. Part of the liquid supply pipelines is located in the vacuum outer sleeves. That is, part of the liquid supply pipelines is located outside the vacuum outer sleeves. The gap 33 is used for vacuuming and pulling and circulating the residual liquid.

In an embodiment, as shown in FIG. 1, the wet processing device further comprises: a liquid supply component 50, the other end of the first channel 20 away from the nozzle 10 being communicated with the liquid supply component 50; wherein a first valve 21 is provided on the first channel 20. The opening and closing of the first valve 21 can control the switching on and off of the first channel 20, that is, control whether or not the liquid supply component 50 supplies liquid into the nozzle 10. For example, after opening the first valve 21, the liquid supply component 50 can supply liquid to the nozzle 10 directly through the first channel 20. The liquid supply component 50 is not limited here as long as it can realize the liquid supply function. For example, it may comprise a liquid tank, a water pump, and the like.

In an embodiment, the first valve 21 is a liquid supply valve (which may have a flow control function). The first valve 21 may be a manually controlled mechanical valve, for example a common needle valve, a stop valve, a gate valve, a plug valve, a ball valve or a butterfly valve, etc., or may be an automatically controlled electronic valve, for example a solenoid valve or an electronic valve with a sensor.

In an embodiment, the wet processing device further comprises: a vacuum generator 60, the other end of the second channel 30 away from the opening 31 being communicated with the vacuum generator 60; wherein a second valve 34 is provided on the second channel 30. The opening and closing of the second valve 34 can control the switching on and off of the second channel 30, that is, control whether or not the vacuum generator 60 can pull away the liquid flowing out of the nozzle 10. For example, after opening the second valve 34, the vacuum generator 60 provides negative pressure to the second channel 30 so as to pull away the liquid flowing out of the nozzle 10.

In an embodiment, the second valve 34 is a vacuum valve, for example a ball valve or a butterfly valve, etc. It may be a mechanical valve or an electronic valve.

In an embodiment, the wet processing device further comprises a controller, connected to the sensor 40 and to the second valve 34, so as to control the communication of the second channel 30 through the second valve 34 when the sensor 40 detects that there is the liquid in the nozzle 10. The controller receives the detection signal obtained by the sensor 40, and determines whether there is liquid in the nozzle 10; and when there is liquid in the nozzle 10, it can control the second valve 34 to open so that the second channel 30 is switched on, that is, negative pressure is provided to the second channel 30 through the vacuum generator 60 to pull away the liquid flowing out of the nozzle 10.

In an embodiment, the controller comprises an alarm module that is triggered when the sensor 40 detects that there is the liquid in the nozzle 10. While the second channel 30 pulls away the liquid, the alarm module can play a warning function.

In an embodiment, the alarm module and the second valve 34 can respond at the same time.

In an embodiment, as shown in FIG. 1, the wet processing device further comprises: a third channel 70 in which negative pressure is formed, the third channel 70 being communicated with the first channel 20, and the third channel 70 being set in a manner that it can be switched on or off. The third channel 70 can pull away the residual liquid in the first channel 20 and the nozzle 10 after the first channel 20 stops supplying liquid to the nozzle 10. However, if the negative pressure in the third channel 70 is insufficient, the liquid in part of the pipeline of the first channel 20 may drop, that is, drop through the nozzle 10. In this case, with the help of the sensor 40 and the second channel 30, it is ensured that no liquid will drop.

In an embodiment, as shown in FIG. 1, the wet processing device further comprises: a carrying table 80 configured to carry a wafer 1, the carrying table 80 comprising a receiving groove 81 in which the wafer 1 is located, the opening 31 being arranged opposite to the notch of the receiving groove 81; wherein the third channel 70 is communicated with the receiving groove 81.When the wafer 1 is processed by the wet processing device, a large amount of liquid will be accumulated in the receiving groove 81. In this case, the liquid accumulated in the receiving groove 81 can be recycled in time by communicating with the receiving groove 81 through the third channel 70.

In an embodiment, the third channel 70 is a return pipeline, a third valve 71 is provided on the return pipeline, and the return pipeline is communicated with the receiving tank 81 through a branch return pipeline 72; wherein the third channel 70 comprises a first connection port 73 connected to the first channel 20 and a second connection port 74 connected to the branch return pipeline 72, the third valve 71 is located between the first connection port 73 and the second connection port 74. The third valve 71 is configured to control the switching on and off of the first channel 20 and the third channel 70, that is, to control whether or not the liquid in the first channel 20 can enter the liquid recycle portion 90 through the first channel 20. The receiving groove 81 needs to be communicated with the third channel 70 through the branch return pipeline 72, that is, the liquid flows into the liquid recycle portion 90 in real time.

In an embodiment, the third valve 71 is a return valve. It may be a manually controlled mechanical valve, for example a common needle valve, a stop valve, a gate valve, a plug valve, a ball valve or a butterfly valve, etc., or may be an automatically controlled electronic valve, for example a solenoid valve or an electronic valve with a sensor.

In an embodiment, the wet processing device is a wet cleaning device, a wet etching device or a wet electroplating device. The wet processing device is suitable for wet cleaning processes such as water washing, wet etching processes and wet electroplating processes, mainly depending upon the liquid conveyed by the first channel 20 being cleaning liquid (for example water), etching liquid or electroplating liquid. The wet processing device may be a wet cleaning device, a wet etching device (for example a monolithic water washing and etching machine) or a wet electroplating device.

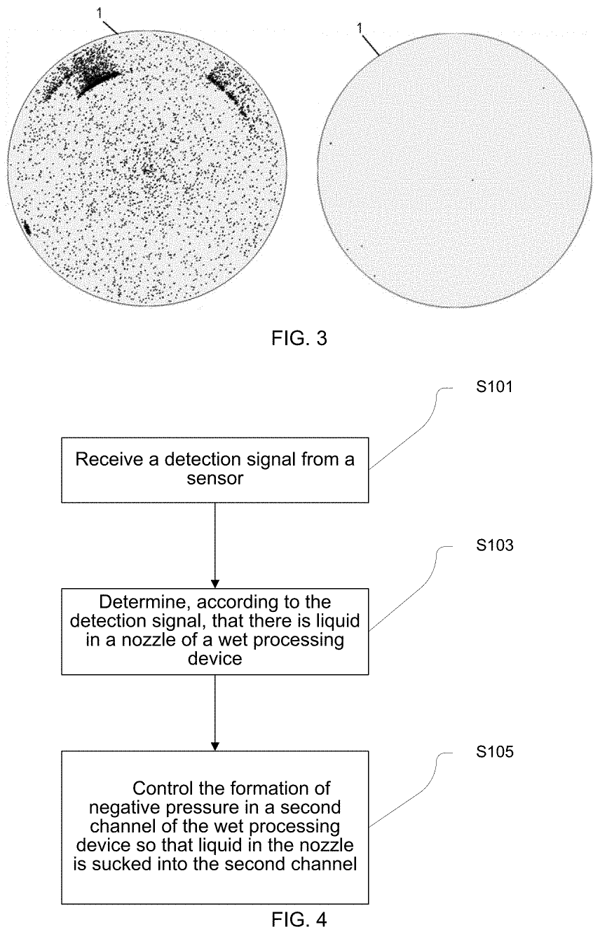

In an embodiment, the wet processing device is a monolithic water washing and etching machine in which a vacuum outer sleeve is additionally provided outside the liquid supply pipeline, and a photoelectric sensor is additionally provided outside the vacuum outer sleeve, namely the sending end 41 and the receiving end 42. When liquid drops from the nozzle 10, the presence of droplets on the inner wall of the nozzle 10 will affect the light sensation value received by the receiving end 42, so that the liquid dropping is detected. In this case, the alarm module of the machine alarms and opens the second valve 34, and negative pressure is formed in the vacuum outer sleeve. When the droplet falls to the spout 11, it will be pulled back from the vacuum outer sleeve and will not drop on the wafer 1. The photoelectric sensor can detect the liquid dropping timely, and pull back the droplet. The problem that the engineer is unable to notice this problem in time when liquid drops from the nozzle 10 is avoided. Thus, the product yield is improved. As shown in FIG. 3, the left side view is a schematic structure diagram of a wafer obtained by the wet processing device with liquid dropping. It may be found that there is a large number of defects on the surface of the wafer 1. The right side view is a schematic structure diagram of a wafer obtained by the wet processing device without liquid dropping. It may be found that there is no obvious defect on the surface of the wafer 1.

An embodiment of the present disclosure further provides a control method for a wet processing device. Referring to FIG. 4, the control method comprises:

S101: receiving a detection signal from a sensor;

S103: determining, according to the detection signal, that there is liquid in a nozzle of a wet processing device; and

S105: controlling the formation of negative pressure in a second channel of the wet processing device so that liquid in the nozzle is pulled into the second channel.

In the control method for a wet processing device in an embodiment of the present disclosure, a detection signal is received and a determination is made as to whether there is liquid in the nozzle according to the detection signal. That is, when there is liquid in the nozzle, negative pressure is formed in the second channel to pull the liquid in the nozzle into the second channel to prevent liquid from dropping from the nozzle.

In an embodiment, the control method for a wet processing device further comprises: controlling an alarm module to give an alarm while controlling the formation of negative pressure in the second channel.

In an embodiment, the control method for a wet processing device further comprises: controlling the formation of negative pressure in a third channel, so as to pull liquid in the first channel into the third channel. This process is performed after the nozzle stops spraying liquid to the wafer.

In an embodiment, the control method for a wet processing device may be used to control the wet processing device.

The present disclosure further provides a computer-readable storage medium having a computer program stored thereon that, when executed by a processor, implements steps of the control method for a wet processing device described above.

In some possible implementations, various aspects of the present disclosure may be implemented in the form of a program product which comprises program codes. When the program product is run on a terminal device, the program codes are used to enable the terminal device to execute the steps according to various exemplary implementations of the present disclosure, which have been described in the control method for a wet processing device in this specification.

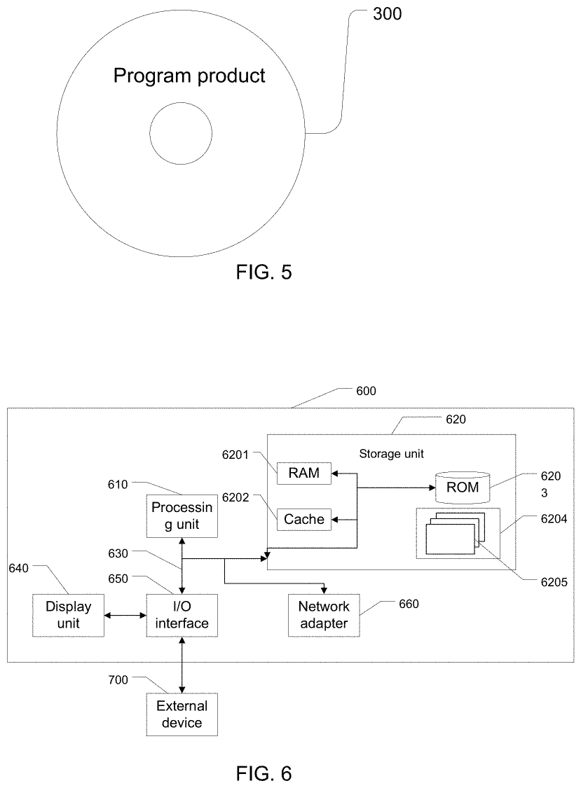

Referring to FIG. 5, a program product 300 for implementing the method according to an implementation of the present disclosure is described. It may be a portable compact disk read-only memory (CD-ROM) and may comprise program codes, and may be run on a terminal device, for example, a personal computer. However, the program product in the present disclosure is not limited thereto. In this document, the computer-readable storage medium may be any tangible medium that contains or stores a program, and the program may be used by or together with an instruction execution system, apparatus, or device.

The program product may be any combination of one or more readable media. The readable medium may be a readable signal medium or readable storage medium. The readable storage medium may be, but not limited to, an electrical, magnetic, optical, electromagnetic, infrared, or semiconductor system, apparatus, or device, or any combination thereof. More specific examples (non-exhaustive list) of the readable storage medium comprise: electric connections having one or more wires, portable disks, hard disks, random access memories (RAMs), read-only memories (ROMs), erasable programmable read-only memories (EPROMs or flash memories), optical fibers, portable compact disk read-only memories (CD-ROMs), optical storage devices, magnetic storage devices, or any suitable combination of the above.

The computer-readable storage medium may comprise data signals propagated in the baseband or as part of carriers, and may carry readable program codes. Such propagated data signals may be in various forms, including but not limited to electromagnetic signals, optical signals, or any suitable combination thereof. The readable storage medium may be any readable medium other than the readable storage medium. The readable medium may send, propagate, or transmit the program used by or together with an instruction execution system, apparatus, or device. The program codes contained in the readable storage medium may be transmitted by any suitable medium, including but not limited to wireless, wired, optical cable, RF, etc., or any suitable combination thereof.

The program code used to perform the operations of the present disclosure may be written in a combination of one or more programming languages. The programming languages include object-oriented programming languages such as Java, C++, and conventional procedural programming languages such as “C” language or similar programming languages. The program code may be executed entirely on the user's computing device, partly on the user's computing device, as an independent software package, partly on the user's computing device and partly executed on a remote computing device, or entirely executed on the remote computing device or server. In the case of a remote computing device, the remote computing device may be connected to the user's computing device through any kind of networks, including a local area network (LAN) or a wide area network (WAN), or may be connected to an external computing device (for example, connected over Internet by the Internet service provider).

The present disclosure further provides an electronic device, comprising: a processor; and a memory configured to store instructions executable by the processor, wherein the processor is configured to execute the control method for a wet processing device described above by executing the executable instructions.

It may be understood by those skilled in the art that various aspects of the present disclosure may be implemented as systems, methods, or program products. Therefore, various aspects of the present disclosure may be specifically implemented in the following forms: only hardware implementations, only software implementations (comprising firmware, microcode, etc.), or a combination of hardware and software implementations, which may be collectively referred to herein as “circuits”, “modules” or “systems”.

The electronic device 600 according to this implementation of the present disclosure will be described below with reference to FIG. 6. The electronic device 600 shown in FIG. 6 is only an example, and does not form any limitation to the functions and application range of the embodiments of the present disclosure.

As shown in FIG. 6, the electronic device 600 is embodied as a general-purpose computing device. The components of the electronic device 600 may comprise, but not limited to, at least one processing unit 610, at least one storage unit 620, a bus 630 connecting different system components (comprising the storage unit 620 and the processing unit 610), a display unit 640, and the like.

The storage unit stores program codes and the program codes may be executed by the processing unit 610 so that the processing unit 610 executes the steps according to various exemplary implementations of the present disclosure, which have been described in the control method for a wet processing device in this specification.

The storage unit 620 may comprise readable media in the form of volatile memories, for example random access memory (RAM) 6201 and/or cache 6202, and may further comprise read-only memory (ROM) 6203.

The storage unit 620 may further comprise a program/utility 6204 having a set of (at least one) program modules 6205. Such program modules 6205 include, but are not limited to, an operating system, one or more application programs, other program modules, and program data. Each of these examples or a combination thereof may comprise the implementation of a network environment.

The bus 630 may be one or more of several types of bus structures, including storage unit buses or storage unit controllers, peripheral buses, accelerated graphics ports, processing units, or local buses using any of multiple bus structures.

The electronic device 600 may communicate with one or more external devices 700 (for example, a keyboard, a pointing device, a Bluetooth device, etc.), and may communicate with one or more devices that enable a user to interact with the electronic device 600, and/or communicate with any device (for example, a router, a modem, etc.) that enables the electronic device 600 to communicate with one or more other computing devices. Such communication may be performed through an input/output (I/O) interface 650. Furthermore, the electronic device 600 may communicate with one or more networks (for example, a local area network (LAN), a wide area network (WAN), and/or a public network, for example the Internet) through a network adapter 660. The network adapter 660 may communicate with other modules of the electronic device 600 through the bus 630. It should be understood that, although not shown, other hardware and/or software modules may be used together with the electronic device 600, including but not limited to: microcode, device drivers, redundant processing units, external disk drive arrays, RAID systems, tape drives and data backup storage systems, etc.

Through the above description of the implementations, those skilled in the art can easily understand that the exemplary implementations described here may be implemented by software, or may be implemented by the combination of software with necessary hardware. Therefore, the technical solutions according to the implementations of the present disclosure may be embodied in the form of software products which may be stored in a non-volatile storage medium (which may be a CD-ROM, a USB flash disk, a removable hard disk, etc.) or on the network, including several instructions to enable a computing device (which may be a personal computer, a server, or a network device, etc.) to execute the control method for a wet processing device according to the implementations of the present disclosure.

Those skilled in the art will readily think of other embodiments of the present disclosure by considering the specification and practicing the invention disclosed herein. The present disclosure is intended to encompass any variations, uses, or adaptive changes of the present invention. These variations, uses, or adaptive changes follow the general principles of the present disclosure and include common knowledge or conventional technical means in the technical field that are not disclosed in the present disclosure. The specification and the exemplary implementations are just exemplary, and the true scope and spirit of the present disclosure are defined by the appended claims.

It should be understood that the present disclosure is not limited to the precise structures that have been described above and shown in the drawings, and various modifications and changes may be made without departing from its scope. The scope of the present disclosure is defined only by the appended claims.

1. A wet processing device, comprising:
a first channel;
a nozzle comprising a spout, the nozzle being communicated with the first channel;
a second channel in which negative pressure is formed, the second channel comprising an opening, the spout eing located in the second channel, the opening being located below the spout; and
a sensor configured to detect whether there is liquid in the nozzle.

2. The wet processing device according to claim 1, wherein the second channel comprises a tapered channel, and a small-diameter end of the tapered channel is the opening.

3. The wet processing device according to claim 1, wherein at least part of the first channel is a liquid supply pipeline, the nozzle is connected to the liquid supply pipeline, at least part of the second channel is a vacuum outer sleeve, the nozzle is located in the vacuum outer sleeve, and at least part of the liquid supply pipeline is located in the vacuum outer sleeve;
wherein, between the nozzle and the vacuum outer sleeve, and between the liquid supply pipeline and the vacuum outer sleeve, there is a gap for the liquid to circulate.

4. The wet processing device according to claim 1, further comprising:
a liquid supply component, the other end of the first channel away from the nozzle being communicated with the liquid supply component;
wherein a first valve is provided on the first channel.

5. The wet processing device according to claim 1, further comprising:
a vacuum generator, the other end of the second channel away from the opening being communicated with the vacuum generator;
wherein a second valve is provided on the second channel.

6. The wet processing device according to claim 5, further comprising:
a controller, connected to the sensor and to the second valve, so as to control communication of the second channel through the second valve when the sensor detects that there is the liquid in the nozzle.

7. The wet processing device according to claim 6, wherein the controller comprises an alarm module that is triggered when the sensor detects that there is the liquid in the nozzle.

8. The wet processing device according to claim 1, further comprising:
a third channel in which negative pressure is formed, the third channel being communicated with the first channel, and the third channel being set in a manner that it can be switched on or off.

9. The wet processing device according to claim 8, further comprising:
a carrying table configured to carry a wafer, the carrying table comprising a receiving groove, the wafer is located in the receiving groove, the opening being arranged opposite to a notch of the receiving groove;
wherein the third channel is communicated with the receiving groove.

10. The wet processing device according to claim 9, wherein the third channel is a return pipeline, a third valve is provided on the return pipeline, and the return pipeline is communicated with the receiving tank through a branch return pipeline;
wherein the third channel comprises a first connection port connected to the first channel and a second connection por connected to the branch return pipeline, the third valve is located between the first connection port and the second connection port.

11. The wet processing device according to claim 1, wherein the wet processing device is a wet cleaning device, a wet etching device, or a wet electroplating device.

12. A control method for a wet processing device, comprising:
receiving a detection signal from a sensor;
determining, according to the detection signal, that there is liquid in a nozzle of a wet processing device; and
controlling the formation of negative pressure in a second channel of the wet processing device so that the liquid in the nozzle is pulled into the second channel.

13. The control method for the wet processing device according to claim 12, further comprising:
controlling an alarm module to give an alarm while controlling the formation of negative pressure in the second channel.

14. The control method for a wet processing device according to claim 12, further comprising:
controlling the formation of negative pressure in a third channel of the wet processing device, so as to pull the liquid in the first channel into the third channel; wherein the nozzle is communicated with the first channel.

15. A non-transitory computer-readable storage medium having a computer program stored thereon that, when executed by a processor, implements steps of the control method for a wet processing device according to claim 12.

16. An electronic device implementing the control method for the wet processing device according to claim 12, comprising:
a processor; and
a memory configured to store instructions executable by the processor,
wherein the processor is configured to execute operations of the control method.
